(19) United States
(12) Patent Application Publication
(10) Pub. No.: US 2023/0191547 A1
(43) Pub. Date: Jun. 22, 2023

(54) APPARATUS AND METHOD FOR CONTROLLING CHUCKING FORCE

(71) Applicant: Samsung Electronics Co., Ltd., Suwon-si (KR)

(72) Inventors: Jeongdu KIM, Seoul (KR); Sunghyup KIM, Hwaseong-si (KR); Hyeonjin KIM, Seoul (KR); Jonggu LEE, Seoul (KR); Dongkyeng HAN, Suwon-si (KR)

(73) Assignee: Samsung Electronics Co., Ltd., Suwon-si (KR)

(21) Appl. No.: 17/940,265

(22) Filed: Sep. 8, 2022

(30) Foreign Application Priority Data
Dec. 20, 2021 (KR) 10-2021-0182532

(51) Int. Cl. B23Q 3/15; H01L 21/683

(52) U.S. Cl. CPC B23Q 3/15; H01L 21/6833

(57) ABSTRACT

An apparatus includes a chuck having an upper surface configured to support a substrate; a fixing unit configured to generate chucking force to fix the substrate to the chuck in a first perpendicular direction and applying the chucking force to the substrate; and a controller configured to divide the chuck into a plurality of zones on a plane perpendicular to the first direction, based on reference overlay distribution corresponding to a degree of overlay deterioration when the substrate is fixed to the upper surface of the chuck, and individually control respective magnitudes of the chucking force applied to each of the plurality of zones. The controller is configured to reduce a magnitude of chucking force applied to a zone including a region having a high degree of overlay deterioration, among the plurality of zones, in the reference overlay distribution.

### CROSS-REFERENCE TO RELATED APPLICATION

This application claims benefit of priority to Korean Patent Application No. 10-2021-0182532, filed on Dec. 20, 2021 in the Korean Intellectual Property Office, the disclosure of which is incorporated herein by reference in its entirety.

### BACKGROUND

The present inventive concepts relate to apparatuses and methods for controlling chucking force.

A semiconductor process may be performed on a wafer disposed on a wafer stage. An apparatus for controlling chucking force may entirely control the chucking force applied to the wafer stage, to fix the wafer in semiconductor processing equipment and to maintain flatness of a surface of the wafer. Meanwhile, as semiconductor devices are highly integrated and semiconductor processes thereof are miniaturized, various types of process defects may occur during semiconductor processes performed by placing a wafer on an upper surface of a wafer stage. For example, as the flatness of the surface of the wafer deteriorates, an overlay defect or the like may occur in the wafer.

### SUMMARY

Some example embodiments of the present inventive concepts control chucking force (e.g., control magnitude of chucking force) applied to a substrate based on overlay distribution, to solve a problem of overlay deterioration, maintain flatness of a surface of the substrate, and further improve production yield of a semiconductor device.

According to some example embodiments of the present inventive concepts, an apparatus for controlling chucking force may include a chuck having an upper surface and being configured to support a substrate on the upper surface of the chuck; a fixing unit configured to generate a chucking force to fix the substrate to the chuck in a first direction and apply the chucking force to the substrate, the first direction perpendicular to the upper surface of the chuck; and a controller configured to divide the chuck into a plurality of zones on a plane based on a reference overlay distribution corresponding to a degree of overlay deterioration of the substrate when the substrate is fixed to the upper surface of the chuck, the plane perpendicular to the first direction, and individually control respective magnitudes of the chucking force applied to each of the plurality of zones. The controller may be configured to reduce a magnitude of the chucking force applied to a zone including a region having a degree of overlay deterioration that is at least one standard deviation greater than an average degree of overlay deterioration, among the plurality of zones, in the reference overlay distribution, such that the reduced magnitude is at least 10% smaller than a maximum magnitude of the chucking force applied to the plurality of zones.

According to some example embodiments of the present inventive concepts, an apparatus for controlling chucking force may include a chuck having an upper surface and configured to support a substrate on the upper surface of the chuck; a fixing unit configured to generate a chucking force to fix the substrate to the chuck, and applying the chucking force to the substrate; and a controller configured to divide the chuck into a plurality of zones and individually control respective magnitudes of the chucking force applied within the plurality of zones, wherein the plurality of zones include a first zone, defined in a position corresponding to a center of the chuck, a second zone spaced apart from the first zone and including a region in a first angular direction, a third zone spaced apart from the first zone and including a region in a second angular direction, different from the first angular direction, and a fourth zone in a position different from the first zone in a radial direction of the chuck, and the second zone and the third zone are between the fourth zone and the first zone.

According to some example embodiments of the present inventive concepts, an apparatus for controlling chucking force may include a chuck having an upper surface and configured to support a substrate on the upper surface of the chuck, a fixing unit configured to generate a chucking force to fix the substrate to the chuck, and apply the chucking force to the substrate, and a controller configured to divide the chuck into a plurality of zones and individually control respective magnitudes of the chucking force within the plurality of zones, wherein the plurality of zones include a first zone, defined in a position corresponding to a center of the chuck, a second zone and a third zone, defined in a position corresponding to an outside of the first zone, and a fourth zone, defined in a position corresponding to an outer edge of the chuck, wherein the second zone and the third zone are between the first zone and the fourth zone, and the controller is configured to control a magnitude of the chucking force applied to the second zone and the third zone to be smaller than a magnitude of the chucking force applied to the first zone and the fourth zone.

According to some example embodiments of the present inventive concepts, a method of controlling chucking force includes measuring reference overlay distribution corresponding to a degree of overlay deterioration when a substrate is fixed to an upper surface of a chuck; dividing the chuck into a plurality of zones based on the reference overlay distribution; individually controlling respective magnitudes of a chucking force applied to the plurality of zones; and fixing the substrate to the chuck using the chucking force.

### BRIEF DESCRIPTION OF DRAWINGS

The above and other aspects, features, and advantages of the present inventive concepts will be more clearly understood from the following detailed description, taken in conjunction with the accompanying drawings, in which:

FIG. 1 is a view simply illustrating semiconductor processing equipment to which an apparatus for controlling chucking force according to some example embodiments of the present inventive concepts is applied.

FIG. 2 is a view simply illustrating an apparatus for controlling chucking force according to some example embodiments of the present inventive concepts.

FIGS. 3 and 4 are views illustrating a principle of operating a fixing unit in an apparatus for controlling chucking force according to some example embodiments of the present inventive concepts.

FIG. 5 is a flowchart illustrating a method for controlling chucking force according to some example embodiments of the present inventive concepts.

FIG. 6 is a view simply illustrating an apparatus for controlling chucking force according to some example embodiments of the present inventive concepts.

FIG. 7 is a flowchart illustrating a method for controlling chucking force according to some example embodiments of the present inventive concepts.

FIG. 8 is a view illustrating a problem of overlay deterioration that can be solved by an apparatus for controlling chucking force according to some example embodiments of the present inventive concepts.

FIG. 9 is a view illustrating a cause of a problem of overlay deterioration that can be solved by an apparatus for controlling chucking force according to some example embodiments of the present inventive concepts.

FIGS. 10A, 10B, and 10C are views illustrating a cause of a problem of overlay deterioration that can be solved by an apparatus for controlling chucking force according to some example embodiments of the present inventive concepts.

FIG. 11 is a view illustrating a principle of operating an apparatus for controlling chucking force according to some example embodiments of the present inventive concepts.

FIG. 12 is a view illustrating characteristics of a substrate to which an apparatus for controlling chucking force according to some example embodiments of the present inventive concepts is applied.

FIG. 13 is a view illustrating a plurality of zones in an apparatus for controlling chucking force according to some example embodiments of the present inventive concepts.

FIGS. 14 and 15 are views illustrating a fixing unit included in an apparatus for controlling chucking force according to some example embodiments of the present inventive concepts.

FIG. 16 is a view illustrating effects of an apparatus for controlling chucking force according to some example embodiments of the present inventive concepts.

FIG. 17 is a view illustrating a plurality of zones in an apparatus for controlling chucking force according to some example embodiments of the present inventive concepts.

FIG. 18 is a view illustrating a plurality of zones in an apparatus for controlling chucking force according to some example embodiments of the present inventive concepts.

FIG. 19 is a view illustrating a plurality of zones in an apparatus for controlling chucking force according to some example embodiments of the present inventive concepts.

FIG. 20 is a view illustrating a plurality of zones in an apparatus for controlling chucking force according to some example embodiments of the present inventive concepts.

### DETAILED DESCRIPTION

Hereinafter, some example embodiments of the present inventive concepts will be described with reference to the accompanying drawings.

In the drawings and in the specification, terms such as “first,” “second,” “third,” and the like may be used to describe various components, but the components are not limited by the terms. Terms such as “first,” “second,” “third,” and the like may be used for the purpose of distinguishing one component from another component. For example, without departing from the scope of the present inventive concepts, a “first component” may be referred to as a “second component.”

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular” with regard to other elements and/or properties thereof will be understood to be “perpendicular” with regard to the other elements and/or properties thereof within manufacturing tolerances and/or material tolerances and/or have a deviation in magnitude and/or angle from “perpendicular,” or the like with regard to the other elements and/or properties thereof that is equal to or less than 10% (e.g., a tolerance of ±10%).

Elements and/or properties thereof (e.g., structures, surfaces, directions, or the like) that are “substantially parallel” with regard to other elements and/or properties thereof will be understood to be “parallel” with regard to the other elements and/or properties thereof within manufacturing tolerances and/or material tolerances and/or have a deviation in magnitude and/or angle from “parallel,” or the like with regard to the other elements and/or properties thereof that is equal to or less than 10% (e.g., a tolerance of ±10%).

Elements and/or properties thereof (e.g., structures, surfaces, directions, or the like) that are “substantially coplanar” with regard to other elements and/or properties thereof will be understood to be “coplanar” with regard to the other elements and/or properties thereof within manufacturing tolerances and/or material tolerances and/or have a deviation in magnitude and/or angle from “coplanar,” or the like with regard to the other elements and/or properties thereof that is equal to or less than 10% (e.g., a tolerance of ±10%).

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

It will be understood that elements and/or properties thereof described herein as being the “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

While the term “same,” “equal” or “identical” may be used in description of some example embodiments, it should be understood that some imprecisions may exist. Thus, when one element is referred to as being the same as another element, it should be understood that an element or a value is the same as another element within a desired manufacturing or operational tolerance range (e.g., ±10%).

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

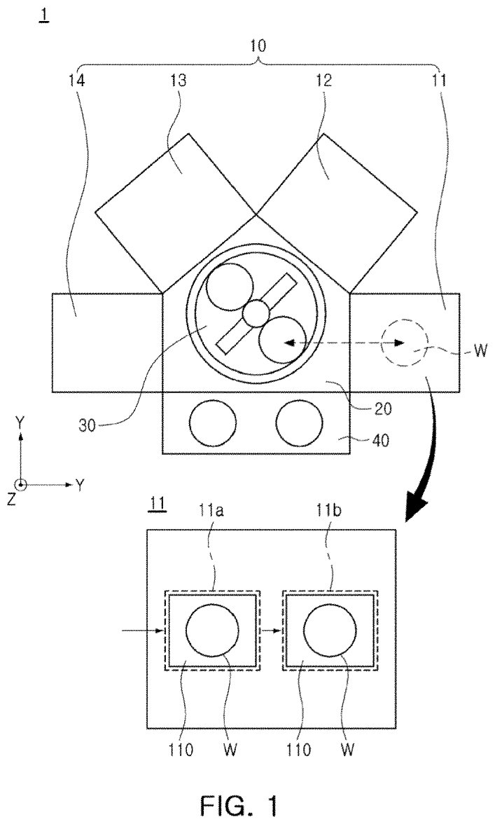

FIG. 1 is a view simply illustrating semiconductor processing equipment to which an apparatus for controlling chucking force according to some example embodiments of the present inventive concepts is applied.

Referring to FIG. 1, semiconductor processing equipment 1 to which an apparatus for controlling chucking force according to some example embodiments of the present inventive concepts is applied may include a plurality of process chambers 11, 12, 13, and 14 (10) for performing a semiconductor process with respect to a substrate W. For example, the plurality of process chambers (10) may include a deposition process chamber for performing a deposition process, a polishing process chamber for performing a chemical mechanical polishing (CMP) process, an etching process chamber for generating plasma including radicals and ions of a source gas or using an etchant or the like to remove at least a portion of device layers included in the substrate W, a photo process chamber for performing an exposure process (e.g., a lithography process) of circuits and patterns on the substrate W, or the like. The plurality of process chambers (10) may include a test process chamber for testing the substrate W during a process or after completion of the process.

For example, the substrate W may be a semiconductor substrate on which the semiconductor process is performed, or a wafer formed of a semiconductor material such as silicon or the like. Semiconductor processes performed in the plurality of process chambers (10) may form semiconductor devices on the substrate W, wiring patterns connected to the semiconductor devices, insulating layers covering the semiconductor devices and the wiring patterns, or the like, and may produce a plurality of semiconductor chips from the substrate W.

For example, the plurality of process chambers 11 to 14 may receive the substrate W through a transfer chamber 20 and a load-lock chamber 40, to perform the semiconductor process. The transfer chamber 20 and the load-lock chamber 40 may include a transfer robot 30, and the transfer robot 30 of the transfer chamber 20 and the transfer robot 30 of the load-lock chamber 40 may transfer the substrate W, which may be a process object, or the like. For example, the transfer robot 30 of the transfer chamber 20 may remove the process object such as the substrate W or the like from the load-lock chamber 40 to transfer the same to the plurality of process chambers 11 to 14, or may transfer the process object between the process chambers 11 to 14. In some example embodiments, the transfer robot may be a handler.

The transfer robot 30 may include a chuck for fixing the process object, and a linear stage for transferring the process object. For example, the chuck may be a wafer stage on which the wafer is disposed.

For example, the chuck may be an electrostatic chuck (ESC) using electrostatic force for fixing the process object. While a process such as an exposure process is performed in the semiconductor process equipment 1 to which an apparatus for controlling chucking force according to some example embodiments of the present inventive concepts is applied, the chuck may use electrostatic force to fix the process object such as the substrate W in a particular (or, alternatively, predetermined) position. For example, the particular (or, alternatively, predetermined) position may include both a position in upward and downward directions, and a position in left and right directions. A plurality of protrusions may be formed on the electrostatic chuck to contact the process object. Depending on a process, the electrostatic chuck may operate as a lower electrode. However, this is only illustrative and is not limited.

The chuck for fixing the process object may be a vacuum chuck for fixing the process object by using a suction force. The vacuum chuck may suction gas between the vacuum chuck and the substrate W, which may be the process object, to fix the substrate W to an upper surface of the vacuum chuck.

Referring to FIG. 1, in the semiconductor process equipment 1 to which an apparatus for controlling chucking force according to some example embodiments of the present inventive concepts is applied, the transfer robot 30 of the transfer chamber 20 may remove the substrate W from the load-lock chamber 40 to transfer the same to the transfer chamber 20, and may transfer the substrate W, which may be the process object, to a process chamber 11.

For example, the process chamber 11 may be a photo process chamber for performing an exposure process, and the exposure process may be performed on the substrate W, which may be the process object, in the process chamber 11. In some example embodiments, the process object is not limited to the wafer. For example, the substrate W may be various substrates other than the wafer, for example, a mother substrate for a display.

The substrate W transferred to the process chamber 11 may be fixed to an upper surface of a chuck 110 during a process. For example, the process chamber 11 may include a first region 11a and a second region 11b. The first region 11a may be a region for measuring overlay distribution indicating a degree of overlay deterioration when the substrate W is fixed to the upper surface of the chuck 110. The second region 11b may be a region in which an exposure process is performed on the substrate W. The substrate W transferred to the process chamber 11 may be transferred to the second region 11b through the first region 11a, and an exposure process may be performed. However, this is only illustrative and is not limited.

An apparatus for controlling chucking force according to some example embodiments of the present inventive concepts may fix the substrate W to the upper surface of the chuck 110 using a fixing unit. The apparatus for controlling chucking force may divide the chuck 110 into a plurality of zones, to individually control a magnitude of chucking force for the plurality of zones (also referred to herein as individually controlling respective magnitudes of the chucking force applied to each of the plurality of zones). The chucking force may be applied to a substrate W corresponding to the plurality of zones, and the substrate W may be fixed to the upper surface of the chuck 110 while maintaining flatness thereof based on the applied chucking force. For example, the chucking force may be defined as fixing force.

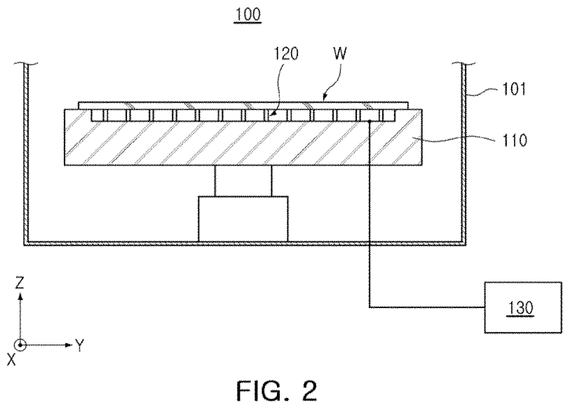

FIG. 2 is a view simply illustrating an apparatus for controlling chucking force according to some example embodiments of the present inventive concepts.

Referring to FIG. 2, an apparatus 100 for controlling chucking force according to some example embodiments of the present inventive concepts may include a chuck 110, a fixing unit 120, and a controller 130. The apparatus 100 may be applied to at least one of the plurality of process chambers 11 to 14 illustrated in FIG. 1. The chuck 110 and the fixing unit 120 may be disposed in a process chamber 101, and the controller 130 may be disposed outside the process chamber 101.

A substrate W may be disposed on an upper surface of the chuck 110. The fixing unit 120 may generate chucking force for fixing the substrate W to the chuck 110 in a first direction (e.g., a Z-direction), perpendicular to the upper surface of the chuck 110. The fixing unit 120 may apply the chucking force to the substrate W. The fixing unit 120 may be disposed between the chuck 110 and the substrate W, but this is only illustrative and is not limited thereto, and the fixing unit 120 may be configured to be included in the chuck 110.

When the substrate W is fixed to the upper surface of the chuck 110, the substrate W may not be fixed in a perfectly flat manner to the upper surface of the chuck 110. For example, the substrate W may be fixed in a curved manner to the upper surface of the chuck 110 in some regions. Curving occurring in the substrate W during the semiconductor process may reduce accuracy of the process. For example, an overlay problem related to pattern alignment may occur, such as not being able to perform a process at an exact position of the substrate W, or the like.

The controller 130 may divide the chuck 110 into a plurality of zones on a plane, perpendicular to the first direction, based on a degree of overlay deterioration when the substrate W is fixed to the upper surface of the chuck 110. For example, the degree of overlay deterioration may be reference overlay distribution determined from overlay distribution previously measured. However, this is only illustrative and is not limited.

The controller 130 may individually control chucking force for the plurality of zones (e.g., individually control respective magnitudes of the chucking force applied to each of the plurality of zones). The controller 130 may detect a region having a high degree (e.g., magnitude) of overlay deterioration (e.g., a degree of overlay deterioration that at least meets a stored threshold degree of overlay deterioration), based on the reference overlay distribution. The controller 130 may reduce a magnitude of chucking force applied to a zone including a region having a high degree of overlay deterioration (e.g., a degree of overlay deterioration, as indicated by the reference overlay distribution, that is greater than 1 standard deviation from the average degree of overlay deterioration among the plurality of zones), among the plurality of zones. For example, when a first degree of overlay deterioration of a first zone is greater than a second degree of overlay deterioration of a second zone, the controller may set a first magnitude of the chucking force applied to the first zone to be smaller than a second magnitude of the chucking force applied to the second zone.

For example, the magnitude of the chucking force applied to the zone could be reduced to be to be at least 10% smaller than the maximum magnitude of chucking force applied among the plurality of zones, at least 20% smaller than the maximum magnitude of chucking force applied among the plurality of zones, at least 40% smaller than the maximum magnitude of chucking force applied among the plurality of zones, at least 50% smaller than the maximum magnitude of chucking force applied among the plurality of zones, at least 60% smaller than the maximum magnitude of chucking force applied among the plurality of zones, at least 80% smaller than the maximum magnitude of chucking force applied among the plurality of zones, at least 90% smaller than the maximum magnitude of chucking force applied among the plurality of zones, or the like.

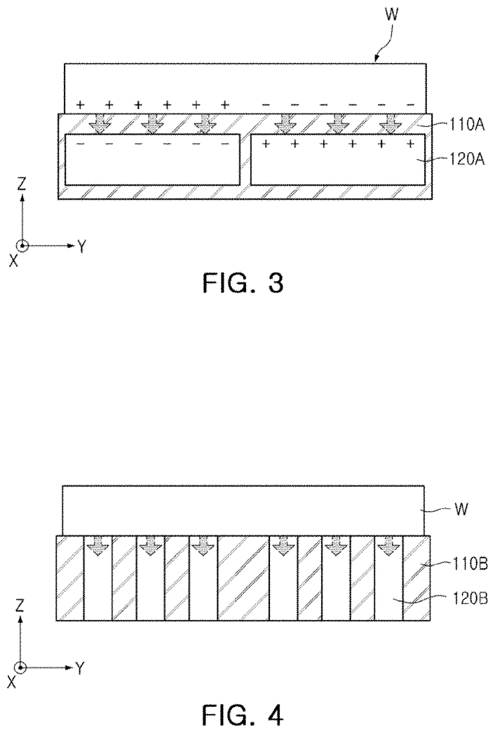

FIGS. 3 and 4 are views illustrating a principle of operating a fixing unit in an apparatus for controlling chucking force according to some example embodiments of the present inventive concepts.

A chuck 110 included in an apparatus 100 for controlling chucking force according to some example embodiments of the present inventive concepts may be an electrostatic chuck (ESC) or a vacuum chuck. A shape and operation principle of a fixing unit 120 may vary depending on the type of the chuck 110. FIGS. 3 and 4 are only views illustrating a principle of operating the fixing unit 120 according to a type of the chuck 110, and a shape thereof is not limited to those illustrated.

Referring to FIG. 3, an electrostatic chuck 110A may include a fixing unit that includes an electrode unit 120A including a plurality of electrodes therein. For example, the electrode unit 120A may include a positive electrode and a negative electrode, and the electrode unit 120A may apply an electrical signal to the plurality of electrodes to generate electrical attractive force between a lower surface of a substrate W and the electrode unit 120A. Therefore, the electrode unit 120A may fix the substrate W to the electrostatic chuck 110A using chucking force composed of the electrical attractive force.

Referring to FIG. 4, a vacuum chuck 110B may include a fixing unit that includes a suction unit 120B having a plurality of holes therein. For example, the suction unit 120B may create a vacuum state between a substrate W and the vacuum chuck 110B through the plurality of holes. Therefore, the suction unit 120B may fix the substrate W to the vacuum chuck 110B using chucking force generated by a difference in pressure.

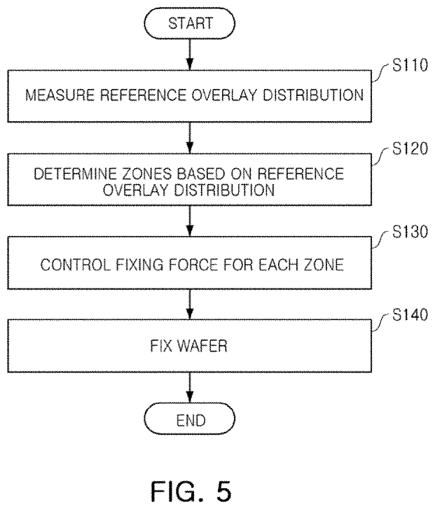

FIG. 5 is a flowchart illustrating a method for controlling chucking force according to some example embodiments of the present inventive concepts.

As described above in the description of FIG. 2, an apparatus 100 for controlling chucking force according to some example embodiments of the present inventive concepts may divide a chuck 110 into a plurality of zones, based on a degree of overlay deterioration when a substrate W is fixed to an upper surface of the chuck 110, and may individually control chucking force for the plurality of zones (e.g., individually control respective magnitudes of the chucking force applied to each of the plurality of zones), to solve a problem of overlay deterioration.

Referring to FIG. 5, a method for controlling chucking force according to some example embodiments of the present inventive concepts may start by measuring reference overlay distribution corresponding to a degree of overlay deterioration when a substrate W is fixed to an upper surface of a chuck 110 (S110).

A controller 130 included in an apparatus 100 for controlling chucking force may divide the chuck 110 into a plurality of zones, based on the measured reference overlay distribution (S120). For example, the plurality of zones may include zones arranged in different positions in a radial direction of the chuck 110, and zones arranged in different positions in an angular direction of the chuck 110.

The controller 130 may individually control chucking force, for example, fixing force applied to the plurality of divided zones (S130). An apparatus 100 for controlling chucking force according to some example embodiments of the present inventive concepts may individually apply chucking force to the plurality of zones, according to a method for controlling chucking force, to fix the substrate W to the upper surface of the chuck 110 while maintaining flatness of the substrate W (S140).

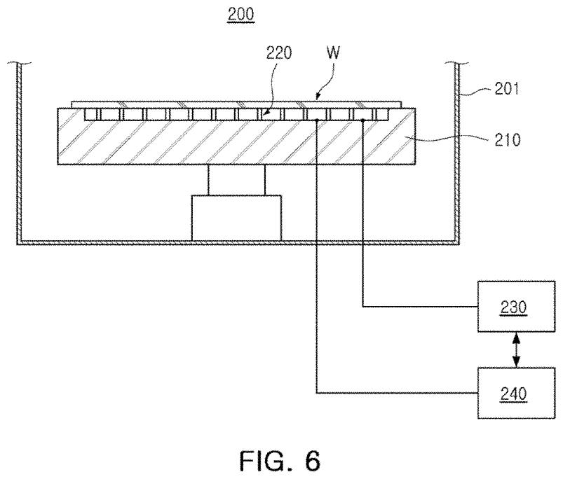

FIG. 6 is a view simply illustrating an apparatus for controlling chucking force according to some example embodiments of the present inventive concepts.

Referring to FIG. 6, a configuration of an apparatus 200 for controlling chucking force according to some example embodiments of the present inventive concepts may correspond to the apparatus 100 for controlling chucking force illustrated in FIG. 2. For example, the apparatus 200 may include a chuck 210 having an upper surface on which a substrate W is disposed surface, a fixing unit 220 generating chucking force for fixing the substrate W to the chuck 210, and a controller 230 controlling the chucking force for each zone to solve a problem of overlay deterioration.

An apparatus 200 for controlling chucking according to some example embodiments of the present inventive concepts may further include an overlay distribution measuring device 240 for measuring a degree of overlay deterioration of the substrate W before or after a process or during the process, unlike the apparatus 100 illustrated in FIG. 2. For example, the overlay distribution measuring device 240 may measure object overlay distribution different from reference overlay distribution, and may transmit a measurement result thereof to the controller 230. The chuck 210 and the fixing unit 220 may be disposed in a process chamber 201, and the controller 230 and the overlay distribution measuring device 240 may be disposed outside the process chamber 201.

The controller 230 may set a plurality of new zones, based on the object overlay distribution. The controller 230 may control chucking force individually for the plurality of new zones.

The apparatus 100 illustrated in FIG. 2 is illustrated as not including a configuration corresponding to the overlay distribution measuring device 240, but this is only illustrative and is not limited. For example, the apparatus 100 may include a separate component corresponding to the overlay distribution measuring device 240, to measure reference overlay distribution for setting a plurality of zones.

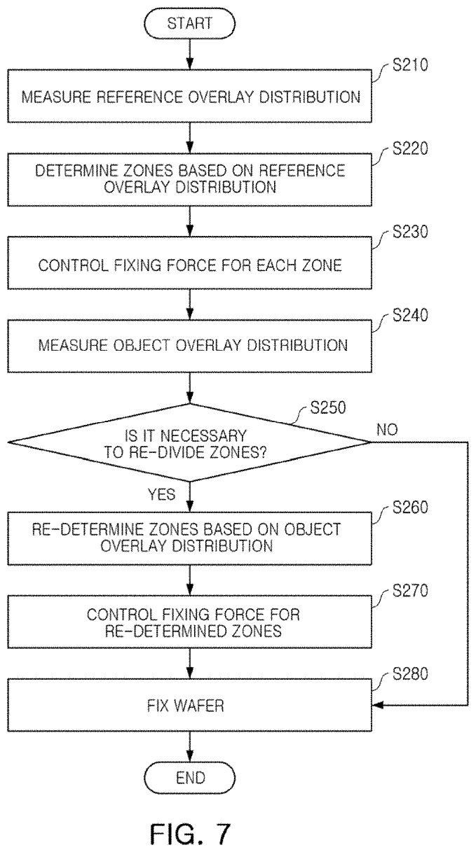

FIG. 7 is a flowchart illustrating a method for controlling chucking force according to some example embodiments of the present inventive concepts.

Referring to FIG. 7, S210 to S230 included in a method for controlling chucking force according to some example embodiments of the present inventive concepts may correspond to S110 to S130 of the method illustrated in FIG. 5, respectively. For example, a method for controlling chucking force may start by measuring reference overlay distribution corresponding to a degree of overlay deterioration when a substrate W is fixed to an upper surface of a chuck 210 (S210). A controller 230 included in an apparatus 200 for controlling chucking force may divide the chuck 210 into a plurality of zones, based on the measured reference overlay distribution (S220), and may individually control chucking force, for example, fixing force applied to the plurality of divided zones (S230).

According to a method for controlling chucking force illustrated in FIG. 7, the apparatus 200 may measure object overlay distribution using an overlay distribution measuring device 240 before or after a process, or during the process (S240). The overlay distribution measuring device 240 may transmit the measured object overlay distribution to the controller 230.

The controller 230 may determine whether the plurality of zones should be reset or not, based on the received object overlay distribution (S250). As necessary, the controller 230 may re-divide the zones, based on the object overlay distribution (S260), and may individually control chucking force for the plurality of re-divided zones (S270).

An apparatus 200 for controlling chucking force according to some example embodiments of the present inventive concepts may fix the substrate W to the upper surface of the chuck 210 while maintaining flatness of the substrate W by chucking force individually controlled for the plurality of zones set based on the reference overlay distribution or the plurality of new zones set based on object overlay distribution, according to a method for controlling chucking force (S280).

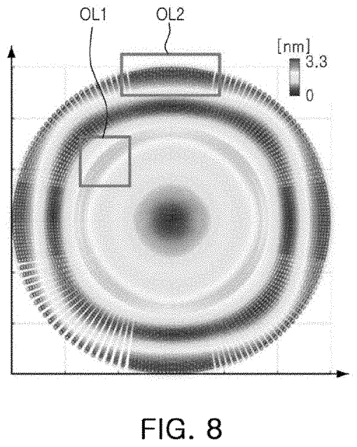

FIG. 8 is a view illustrating a problem of overlay deterioration that can be solved by an apparatus for controlling chucking force according to some example embodiments of the present inventive concepts.

FIG. 8 may illustrate overlay distribution when chucking force is applied evenly throughout a chuck without dividing the chuck into a plurality of zones. Overlay distribution is not limited to those illustrated in FIG. 8. For example, the overlay distribution (also referred to herein as a reference overlay distribution) may be changed, depending on intensity of chucking force applied to a substrate, and when a period of a process for the substrate is prolonged, the overlay distribution may be changed due to an increase in friction between the chuck and the substrate, or the like. In addition, the overlay distribution may be determined by various causes such as anisotropy of a material constituting the substrate, warpage, a pattern of a chip formed on the substrate, a scribe lane, or the like.

Referring to FIG. 8, overlay distribution may be provided as having entirely concentric circles. For example, there may be almost no overlay deterioration in a region corresponding to a center of a chuck, but overlay deterioration may worsen as a distance from the center of the chuck increases. As the distance from the center of the chuck increases by a certain value or more, a degree of overlay deterioration may decrease again, and the degree of overlay deterioration may relatively increase in a region corresponding to an outer edge of the chuck.

The overlay distribution may be changed, depending on an angular direction. For example, in the vicinity of the outer edge of the chuck in which the overlay deterioration is intensified, the overlay deterioration may intensify every 90°. In this case, a second overlay deterioration zone OL2 may be located in a first angular direction. In a region of the chuck between the center and the outer edge in which the overlay deterioration is intensified, the overlay deterioration may intensify every 90°. In this case, a first overlay deterioration zone OL1 may be located in a second angular direction.

In FIG. 8, the first overlay deterioration zone OL1 may be located in a direction, intersecting the second direction (e.g., the X-direction) and the third direction (e.g., the Y-direction), and the second overlay deterioration zone OL2 may be located in the second direction and the third direction. An apparatus for controlling chucking force according to some example embodiments of the present inventive concepts may operate to compensate for deterioration of the first overlay deterioration zone OL1 and the second overlay deterioration zone OL2.

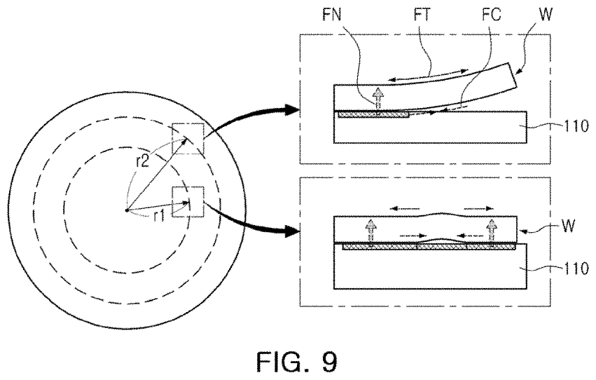

FIG. 9 is a view illustrating a cause of a problem of overlay deterioration that can be solved by an apparatus for controlling chucking force according to some example embodiments of the present inventive concepts.

FIG. 9 is a view illustrating a problem of overlay deterioration that occurs due to non-uniform contact pressure when uniform chucking force is applied to a substrate W. For example, the problem of overlay deterioration illustrated in FIG. 9 may be overlay deterioration that appears in a radial direction of the substrate W.

While a lower surface of the substrate W is in contact with a chuck 110 (and where a normal force FN may be applied), the substrate W may receive a tensile stress FT or a compressive stress FC, depending on a degree of deformation. In a state in which chucking force is applied, deformation of the substrate W may be gradually accumulated from a center of the substrate W in an outward direction. Therefore, as the contact pressure is locally concentrated in some regions, a stress of the substrate W may not be relieved, and thus a problem of overlay deterioration may occur in the concentrated regions.

Referring to FIGS. 8 and 9 together, the first overlay deterioration zone OL1 illustrates a problem of overlay deterioration occurring in a concentric zone having a first radius r1, and the second overlay deterioration zone OL2 illustrates a problem of overlay deterioration occurring in a concentric zone having a second radius r2.

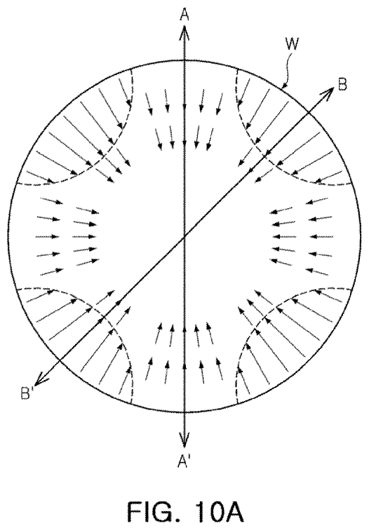

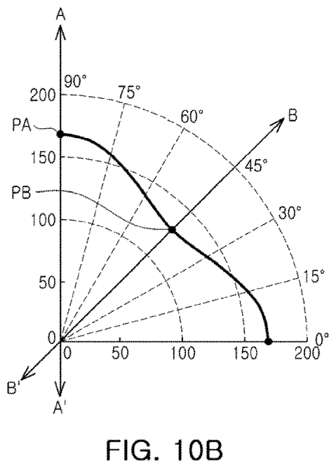

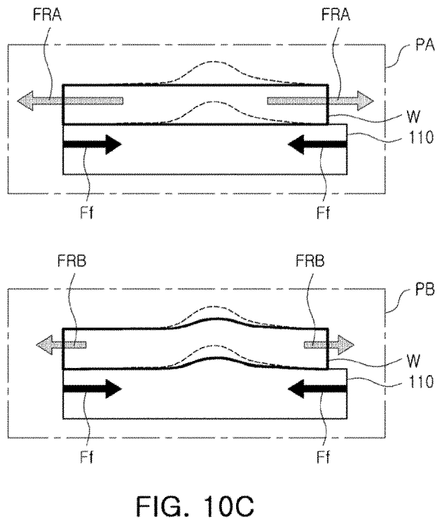

FIGS. 10A, 10B, and 10C are views illustrating a cause of a problem of overlay deterioration that can be solved by an apparatus for controlling chucking force according to some example embodiments of the present inventive concepts.

FIGS. 10A to 10C are views illustrating a problem of overlay deterioration that occurs due to anisotropy of a material constituting a substrate W. For example, the problem of overlay deterioration illustrated in FIGS. 10A to 10C may be overlay deterioration that appears in an angular direction of the substrate W.

Referring to FIGS. 10A and 10B, modulus of elasticity of a substrate W may be changed, depending on a crystal direction of a material constituting the substrate W. The modulus of elasticity of the substrate W may be directly related to deformation force of the substrate W. The deformation force of the substrate W may be represented by arrows, and lengths of the arrows may correspond to magnitudes of the deformation force.

For example, an angle between an AA′ direction and a BB′ direction may be about 45°. Deformation force of the substrate W in the AA′ direction may be weaker than deformation force of the substrate W in the BB′ direction. Therefore, the substrate W may have higher rigidity at a point PA located in the AA′ direction, as compared to those at a point PB located in the BB′ direction, to increase restoring force for resisting deformation. Deformation and overlay deterioration due to concentration of contact pressure may appear more easily at the PB point located in the BB′ direction due to relatively low restoring force, as compared to those at the PA point.

Referring to FIG. 10C, first restoring force FRA at the point PA of the substrate W may be greater than second restoring force FRB at the point PB. Friction force Ff between the substrate W and a chuck 110 may be proportional to normal force, and the normal force may be determined by chucking force applied to the substrate W. Therefore, when the chucking force applied to the substrate W is entirely uniform, the friction force Ff between the substrate W and the chuck 110 may be constant at the PA point and the PB point.

At the PA point of the substrate W, a magnitude of the first restoring force FRA against deformation may be large (e.g., the magnitude of the first restoring force FRA may at least meet a first threshold magnitude) due to relatively high rigidity, to offset the friction force Ff. Therefore, at the PA point of the substrate W, there may be a relatively low possibility of occurring problems of deformation and overlay deterioration of the substrate W.

At the point PB of the substrate W, a magnitude of the second restoring force FRB against deformation may be small (e.g., the magnitude of the second restoring force FRB may be smaller than a second threshold magnitude that is smaller than the first threshold magnitude) due to relatively low rigidity, which may not be sufficient to offset the friction force Ff. Therefore, at the PB point of the substrate W, there may be a relatively high possibility of occurring problems of deformation and overlay deterioration of the substrate W. Accordingly, a zone having a high degree of overlay deterioration may be identified, in some example embodiments, as a zone in which a friction force Ff between the substrate W and the chuck 110 is determined to be constant and in which the magnitude of the second restoring force FRB against deformation is smaller than a second threshold magnitude and thus is smaller than the friction force Ff. Such a zone may have a degree of overlay deterioration, as indicated by the reference overlay distribution, that is greater than 1 standard deviation from the average degree of overlay deterioration among the plurality of zones. In response to such determination, a magnitude of chucking force applied to the zone may be reduced (e.g., reduced to 10% of the maximum chucking force magnitude applied among the plurality of zones).

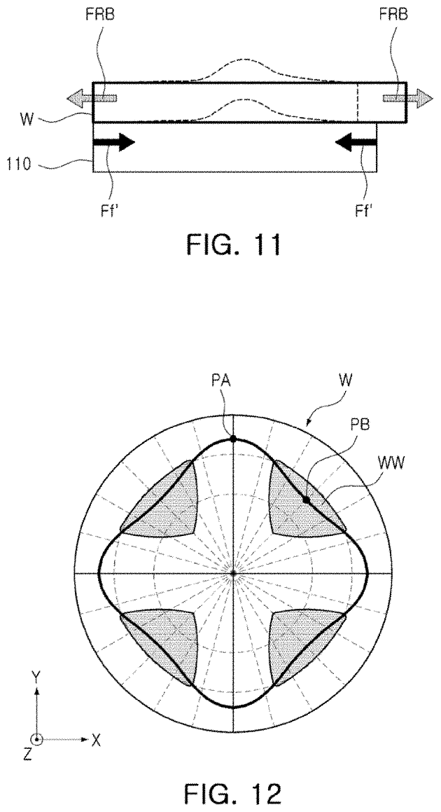

FIG. 11 is a view illustrating a principle of operating an apparatus for controlling chucking force according to some example embodiments of the present inventive concepts.

Referring to FIG. 11, an apparatus for controlling chucking force according to some example embodiments of the present inventive concepts may individually control chucking force applied at a point PB at which possibility of occurring the problems of deformation and overlay deterioration of a substrate W is relatively high (e.g., the possibility of occurring the problems as noted above at least meets a stored threshold possibility value), to reduce possibility of occurring a problem of overlay deterioration.

Forces applied between the substrate W and a chuck 110 illustrated in FIG. 11 may correspond to the forces applied between the substrate W and the chuck 110 at the point PB illustrated in FIG. 10C. For example, a second restoring force FRB against deformation may act at the PB point of the substrate W. In this case, when the second restoring force FRB may not offset friction force Ff′ between the substrate W and the chuck 110, a problem of overlay deterioration may occur on the substrate W.

The friction force Ff′ between the substrate W and the chuck 110 may be proportional to normal force, and the normal force may correspond to chucking force applied to the substrate W. An apparatus for controlling chucking force according to some example embodiments of the present inventive concepts may reduce the chucking force applied to the substrate W at the point PB to reduce the friction force Ff′. Therefore, the apparatus for controlling chucking force may allow the substrate W to slide relatively easily on the chuck 110, to improve a degree of deformation and a degree of overlay deterioration of the substrate W.

FIG. 12 is a view illustrating characteristics of a substrate to which an apparatus for controlling chucking force according to some example embodiments of the present inventive concepts is applied.

Referring to FIGS. 9 to 11, the substrates W may include a region relatively weak to overlay deterioration in the radial and angular directions, respectively. Referring to FIG. 12, a substrate W may include a region relatively weak to overlay deterioration between a region corresponding to a center of the substrate W and a region corresponding to an outer edge of the substrate W in a radial direction. The substrate W may include a region relatively weak to overlay deterioration near a PB point at which restoring force is relatively weak in an angular direction.

Therefore, a weak region WW including the PB point may have a higher probability of causing a problem of overlay deterioration, as compared to other regions (e.g., a probability at least meeting a threshold probability value). An apparatus for controlling chucking force according to some example embodiments of the present inventive concepts may reduce chucking force applied to zones in which a problem of overlay deterioration is high (e.g., in which the aforementioned probability of causing a problem of overlay deterioration, at least meets a threshold probability value and/or for example that the aforementioned probability of causing a problem of overlay deterioration is greater than 1 standard deviation from the average probability of causing a problem of overlay deterioration among the plurality of zones), for example, the weak zone WW, to solve the problem of overlay deterioration.

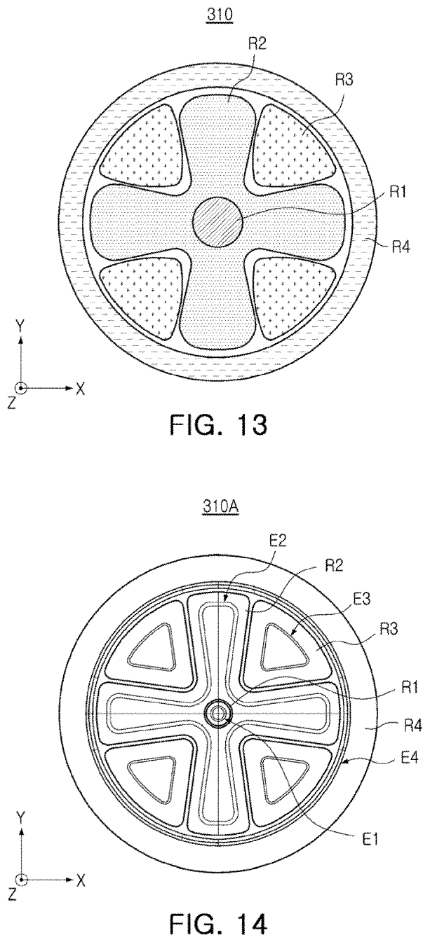

FIG. 13 is a view illustrating a plurality of zones in an apparatus for controlling chucking force according to some example embodiments of the present inventive concepts.

Referring to FIG. 13, an apparatus for controlling chucking force according to some example embodiments of the present inventive concepts may divide a chuck 310 into a plurality of zones R1, R2, R3, and R4 based on reference overlay distribution and/or object overlay distribution.

The plurality of zones R1, R2, R3, and R4 may include a first zone R1 and a fourth zone R4, arranged in different positions in a radial direction of the chuck 310, and a second zone R2 and a third zone R3, arranged in different positions in an angular direction of the chuck 310.

For example, the first zone R1 may be defined in a position corresponding to a center of the chuck 310, the fourth zone R4 may be defined in a position corresponding to an outer edge of the chuck 310, and the first zone R1 and the fourth zone R4 may be spaced apart from each other. The second zone R2 and the third zone R3 may be defined at positions corresponding to an outside of the first zone R1, and the second zone R2 and the third zone R3 may be disposed between the first zone R1 and the fourth zone R4.

The second zone R2 may be spaced apart from the first zone R1 and may include a region in a first angular direction, and the third zone R3 may be spaced apart from the first zone R1 and may include a region in a second angular direction, different from the first angular direction.

In the plurality of zones R1, R2, R3, and R4 set by an apparatus for controlling chucking force according to some example embodiments of the present inventive concepts, at least one of the second zone R2 or the third zone R3 may be disposed between the first zone R1 and the fourth zone R4, in at least one of directions, parallel to an upper surface of the chuck 310.

In at least one of directions, parallel to the upper surface of the chuck 310, at least three or more of the first to fourth zones R1, R2, R3, and R4 may be disposed. For example, in the second direction (e.g., the X-direction) and the third direction (e.g., the Y-direction), the first zone R1, the second zone R2, and the fourth zone R4 may be sequentially located in an outward direction from the center of the chuck 310. In addition, in a direction, intersecting the second and third directions, the first zone R1, the second zone R2, the third zone R3, and the fourth zone R4 may be sequentially located in an outward direction from the center of the chuck 310.

At least one of the plurality of zones R1, R2, R3, and R4 set by an apparatus for controlling chucking force according to some example embodiments of the present inventive concepts may include a plurality of sub-zones individually controlled by a controller.

For example, among the plurality of zones R1, R2, R3, and R4 in the chuck 310 illustrated in FIG. 13, the second zone R2 may extend in the second direction and the third direction with respect to the center of the chuck 310. The third zone R3 may include a plurality of third zones disposed between the second zone R2 and the fourth zone R4 in a direction, parallel to the upper surface of the chuck 310.

Therefore, the plurality of zones R1, R2, R3, and R4 in the chuck 310 illustrated in FIG. 13 may include a circular first zone R1, a cross-shaped second zone R2, a triangular third zone R3, and an annular fourth zone R4.

The controller included in an apparatus for controlling chucking force according to some example embodiments of the present inventive concepts may individually control chucking force for the plurality of zones R1, R2, R3, and R4. For example, a magnitude of the chucking force applied to the first zone may be greater than a magnitude of the chucking force applied to the fourth zone. In addition, a magnitude of the chucking force applied to the fourth zone may be greater than a magnitude of the chucking force applied to the second zone, and a magnitude of the chucking force applied to the second zone may be greater than a magnitude of the chucking force applied to the third zone.

Therefore, an apparatus for controlling chucking force may apply chucking force of a low magnitude to a third zone in which a problem of overlay deterioration is highly likely to occur, to solve the problem of overlay deterioration, and furthermore, to improve yield of a semiconductor device according to a process.

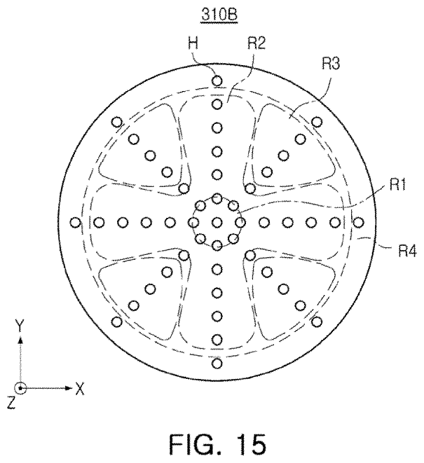

FIGS. 14 and 15 are views illustrating a fixing unit included in an apparatus for controlling chucking force according to some example embodiments of the present inventive concepts.

FIG. 14 illustrates an electrostatic chuck included in an electrostatic chuck 310A included in an apparatus for controlling chucking force according to some example embodiments of the present inventive concepts, and FIG. 15 illustrates a vacuum chuck included in a vacuum chuck 310B included in an apparatus for controlling chucking force according to some example embodiments of the present inventive concepts.

Referring to FIG. 14, an electrostatic chuck 310A may use an electrode unit including electrodes E1, E2, E3, and E4 respectively corresponding to a plurality of zones R1, R2, R3, and R4, to fix a substrate to the electrostatic chuck 310A.

A controller included in an apparatus for controlling chucking force according to some example embodiments of the present inventive concepts may adjust magnitudes of voltages applied to the electrodes E1, E2, E3, and E4 corresponding to each of the plurality of zones R1, R2, R3, and R4, based on reference overlay distribution. For example, similarly to chucking force applied to the plurality of zones R1, R2, R3, and R4, the controller may apply relatively high to relatively low voltages to a first electrode E1, a fourth electrode E4, a second electrode E2, and a third electrode E3.

Referring to FIG. 15, a vacuum chuck 310B may use a suction unit including a plurality of holes H respectively included in a plurality of zones R1, R2, R3, and R4 to create a vacuum state between a substrate and the vacuum chuck 310B, to fix the substrate on the vacuum chuck 310B.

A controller included in an apparatus for controlling chucking force according to some example embodiments of the present inventive concepts may adjust suction intensity through the plurality of holes H corresponding to each of the plurality of zones R1, R2, R3, and R4, based on reference overlay distribution. For example, similarly to chucking force applied to the plurality of zones R1, R2, R3, and R4, the controller may adjust suction intensity in a relatively strong manner through holes H corresponding to the first zone R1, and may adjust the suction intensity in the order of a fourth zone R4, a second zone R2, and a third zone R3.

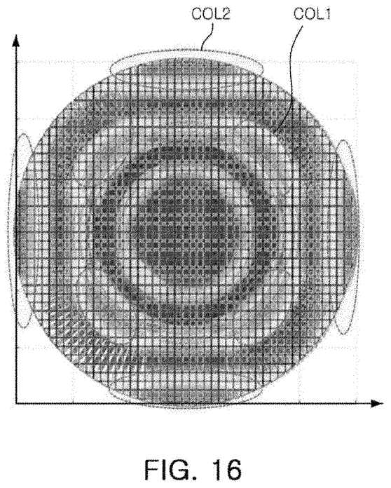

FIG. 16 is a view illustrating effects of an apparatus for controlling chucking force according to some example embodiments of the present inventive concepts.

FIG. 16 may be a view illustrating a degree of overlay compensation by an apparatus for controlling chucking force according to some example embodiments of the present inventive concepts, and may correspond to the reference overlay distribution illustrated in FIG. 8.

Referring to FIG. 16, an apparatus for controlling chucking force according to some example embodiments of the present inventive concepts may divide a chuck into a plurality of zones, and may individually control chucking force for the plurality of zones, to solve a problem of overlay deterioration that may occur when a substrate is fixed to an upper surface of the chuck.

For example, a first overlay compensation zone COL1 may correspond to the first overlay deterioration zone OL1 illustrated in FIG. 8, and a second overlay compensation zone COL2 may correspond to the second overlay deterioration zone OL2. For example, an apparatus for controlling chucking force may compensate for the first and second overlay deterioration zones OL1 and OL2 that may occur when uniform chucking force is entirely applied to the chuck.

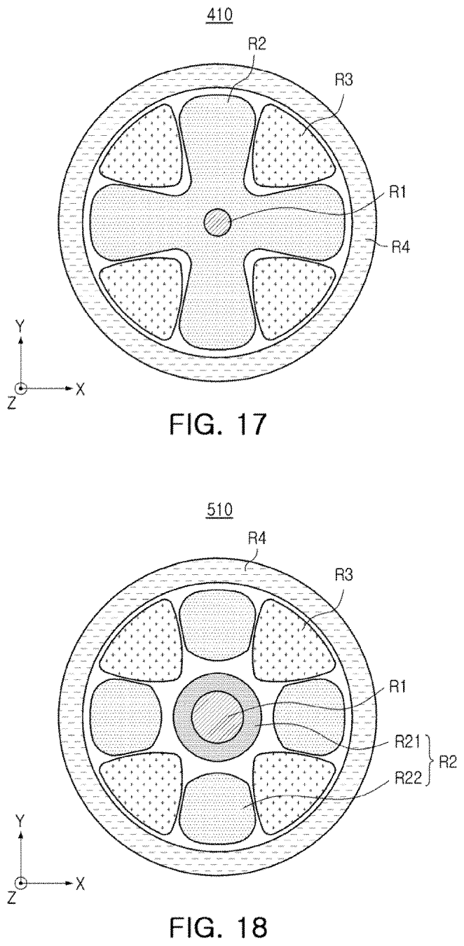

FIG. 17 is a view illustrating a plurality of zones in an apparatus for controlling chucking force according to some example embodiments of the present inventive concepts.

Referring to FIG. 17, an apparatus for controlling chucking force according to some example embodiments of the present inventive concepts may divide a chuck 410 into a plurality of zones R1, R2, R3, and R4 based on reference overlay distribution and/or object overlay distribution. The plurality of zones R1, R2, R3, and R4 in the chuck 410 may correspond to the plurality of zones R1, R2, R3, and R4 in the chuck 310 illustrated in FIG. 13.

For example, among the plurality of zones R1, R2, R3, and R4 in the chuck 410, a second zone R2, a third zone R3, and a fourth zone R4 may be the second zone R2, the third zone R3, and the fourth zone R4 in the chuck 310 illustrated in FIG. 13, respectively. A first zone R1 defined as a region corresponding to a center of the chuck 410 may be smaller than the first zone R1 in the chuck 310 illustrated in FIG. 13. However, this is only illustrative and is not limited thereto, and a size of the first zone R1 may be changed, depending on reference overlay distribution and/or object overlay distribution.

FIG. 18 is a view illustrating a plurality of zones in an apparatus for controlling chucking force according to some example embodiments of the present inventive concepts.

Referring to FIG. 18, an apparatus for controlling chucking force according to some example embodiments of the present inventive concepts may divide a chuck 510 into a plurality of zones R1, R2, R3, and R4 based on reference overlay distribution and/or object overlay distribution. The plurality of zones R1, R2, R3, and R4 in the chuck 510 may correspond to the plurality of zones R1, R2, R3, and R4 in the chuck 310 illustrated in FIG. 13.

At least one of the plurality of zones R1, R2, R3, and R4 set by an apparatus for controlling chucking force according to some example embodiments of the present inventive concepts may include a plurality of sub-zones individually controlled by a controller.

For example, in the chuck 510 of FIG. 18, a second zone R2 may include a first sub-zone R21 and a second sub-zone R22 that may be spaced apart according to a distance from a center of the chuck 510. The controller included in an apparatus for controlling chucking force according to some example embodiments of the present inventive concepts may individually control chucking force applied to the first sub-zone R21 and the second sub-zone R22.

Referring to FIG. 18, the first sub-zone R21 and the first zone R1 are illustrated to form a concentric circle, and the second sub-zone R22 may include a plurality of zones disposed between a plurality of third zones R3. However, this is only illustrative and is not limited. For example, the first zone R1, the third zone R3, and the fourth zone R4 as well as the second zone R2 may be divided into a plurality of sub-regions in radial and angular directions.

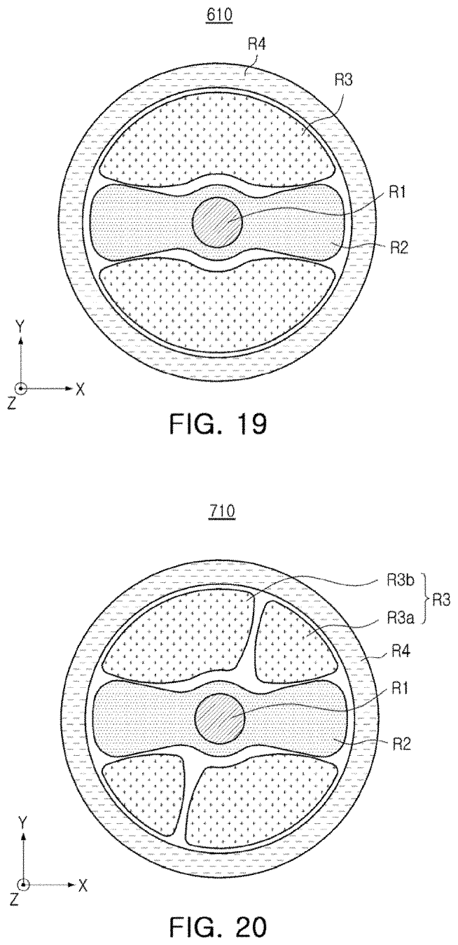

FIG. 19 is a view illustrating a plurality of zones in an apparatus for controlling chucking force according to some example embodiments of the present inventive concepts. FIG. 20 is a view illustrating a plurality of zones in an apparatus for controlling chucking force according to some example embodiments of the present inventive concepts.

Referring to FIGS. 19 and 20, an apparatus for controlling chucking force according to some example embodiments of the present inventive concepts may divide chucks 610 and 710 into a plurality of zones R1, R2, R3, and R4, respectively. The plurality of zones R1, R2, R3, and R4 in each of the chucks 610 and 710 may correspond to the plurality of zones R1, R2, R3, and R4 in the chuck 310 illustrated in FIG. 13.

An apparatus for controlling chucking force according to some example embodiments of the present inventive concepts may set the plurality of zones R1, R2, R3, and R4 to apply chucking force of a small magnitude (e.g., 10% of the maximum magnitude applied among the plurality of zones) to a zone including a region having a high degree of overlay deterioration (e.g., a degree of overlay deterioration that is more than 1 standard deviation greater than the average degree of overlay deterioration among the plurality of zones). Therefore, shapes of the plurality of zones R1, R2, R3, and R4 are not limited, and may be variously set.

For example, a third zone R3 among the plurality of zones R1, R2, R3, and R4 in the chuck 610 illustrated in FIG. 19 may be defined to have a wider range, as compared to the third zone R3 in the chuck 310 illustrated in FIG. 13. Therefore, the third zone R3 of the chuck 610 may include two third zones R3, and a second zone R2 of the chuck 610 may have a structure extending only in the second direction (e.g., the X-direction).

A third zone R3 among the plurality of zones R1, R2, R3, and R4 in the chuck 710 illustrated in FIG. 20 may be defined to have a wider range, as compared to the third zone R3 in the chuck 310 illustrated in FIG. 13. The third zone R3 of the chuck 710 may include four third zones R3 (e.g., including sub-zones R3a and R3b), differently from the third zone R3 of the chuck 610 illustrated in FIG. 19. A second zone R2 of the chuck 710 may have a structure extending only in the second direction, in a similar manner to FIG. 19.

Setting of a plurality of zones by an apparatus for controlling chucking force according to some example embodiments of the present inventive concepts is not limited to those illustrated in FIGS. 13, 17, 18, 19, and 20. For example, the plurality of zones may be set to detect regions prone to a deterioration problem from overlay distribution measurement, and to be spaced apart from other zones based thereon.

As described herein, any devices, electronic devices, modules, units, controllers, circuits, and/or portions thereof according to any of the example embodiments, and/or any portions thereof (including, without limitation, semiconductor processing equipment 1, apparatus 100, chuck 110, fixing unit 120, controller 130, apparatus 200, chuck 210, fixing unit 220, controller 230, overlay distribution measuring device 240, any portions thereof, or the like) may include, may be included in, and/or may be implemented by one or more instances of processing circuitry such as hardware including logic circuits; a hardware/software combination such as a processor executing software; or a combination thereof. For example, the processing circuity more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a solid state drive (SSD), storing a program of instructions, and a processor (e.g., CPU) configured to execute the program of instructions to implement the functionality and/or methods performed by some or all of any devices, electronic devices, modules, units, controllers, circuits, and/or portions thereof according to any of the example embodiments, and/or any portions thereof, including any of the methods shown in any of FIGS. 1 to 20.

According to some example embodiments of the present inventive concepts, an apparatus for controlling chucking force may divide a chuck into a plurality of zones based on overlay distribution, and may individually control chucking force applied to a substrate in the plurality of zones.

According to some example embodiments of the present inventive concepts, an apparatus for controlling chucking force may solve a problem of overlay deterioration and improve production yield of a semiconductor device.

Various advantages and effects of the present inventive concepts are not limited to the above, and will be more easily understood in the process of describing specific embodiments of the present inventive concepts.

While some example embodiments have been illustrated and described above, it will be apparent to those skilled in the art that modifications and variations could be made without departing from the scope of the present inventive concepts as defined by the appended claims.

1. An apparatus, comprising:
a chuck having an upper surface, the chuck configured to support a substrate on the upper surface of the chuck;
a fixing unit configured to generate a chucking force to fix the substrate to the chuck in a first direction and apply the chucking force to the substrate, the first direction perpendicular to the upper surface of the chuck; and
a controller configured to
divide the chuck into a plurality of zones on a plane based on a reference overlay distribution corresponding to a degree of overlay deterioration of the substrate when the substrate is fixed to the upper surface of the chuck, the plane perpendicular to the first direction, and
individually control respective magnitudes of the chucking force applied to each of the plurality of zones,
wherein the plurality of zones includes a first zone having a first degree of overlay deterioration and a second zone having a second degree of overly deterioration smaller than the first degree, and
wherein the controller is configured to set a first magnitude of the chucking force applied to the first zone to be smaller than a second magnitude of the chucking force applied to the second zone.

2. The apparatus of claim 1, wherein the chuck is an electrostatic chuck, and the fixing unit is an electrode unit including electrodes corresponding to each of the plurality of zones.

3. The apparatus of claim 2, wherein the controller is configured to adjust a magnitude of a voltage applied to the electrodes corresponding to each of the plurality of zones, based on the reference overlay distribution.

4. The apparatus of claim 1, wherein the chuck is a vacuum chuck, and the fixing unit is a suction unit including a plurality of holes configured to create a vacuum state between the substrate and the chuck.

5. The apparatus of claim 4, wherein the controller is configured to adjust a suction intensity through the plurality of holes corresponding to each of the plurality of zones, based on the reference overlay distribution.

6. The apparatus of claim 1, wherein
the plurality of zones comprises the first zone, the second zone, a third zone, and a fourth zone,
the first zone and the fourth zone are in different positions in a radial direction of the chuck, and
the second zone and the third zone are in different positions in an angular direction of the chuck.

7. The apparatus of claim 6, wherein the first zone is defined in a position corresponding to a center of the chuck, the second zone is defined in a position corresponding to an outer edge of the chuck, and the first zone and the fourth zone are spaced apart from each other.

8. The apparatus of claim 7, wherein the controller is configured to control a magnitude of the chucking force applied to the first zone to be greater than a magnitude of the chucking force applied to the fourth zone.

9. The apparatus of claim 6, wherein at least one zone of the first to fourth zones comprises a plurality of sub-zones, and the controller is configured to individually control the plurality of sub-zones.

10. The apparatus of claim 6, wherein the second zone extends in a second direction and in a third direction, the second direction perpendicular to the first direction, the third direction perpendicular to the first direction and the second direction with respect to a center of the chuck, wherein the third zone includes a plurality of third zones between the second zone and the fourth zone in a direction that is parallel to the upper surface of the chuck.

11. The apparatus of claim 10, wherein the controller is configured to control a magnitude of the chucking force applied to the second zone to be greater than a magnitude of the chucking force applied to the third zone.

12. The apparatus of claim 10, wherein the controller is configured to control a magnitude of the chucking force applied to the first zone and the fourth zone to be greater than a magnitude of the chucking force applied to the second zone and the third zone.

13. The apparatus of claim 6, wherein, among the plurality of zones, the first zone is circular, the second zone is cross-shaped, the third zone is triangular, and the fourth zone is annular.

14. The apparatus of claim 6, wherein the first zone, the second zone, and the fourth zone are sequentially located in an outward direction from a center of the chuck, in a second direction and in a third direction, the second direction perpendicular to the first direction, the third direction perpendicular to the first direction and the second direction.

15. The apparatus of claim 14, wherein the controller is configured to
control a magnitude of the chucking force applied to the first zone to be greater than a magnitude of the chucking force applied to the fourth zone,
control the magnitude of the chucking force applied to the fourth zone to be greater than a magnitude of the chucking force applied to the second zone, and
control the magnitude of the chucking force applied to the second zone to be greater than a magnitude of the chucking force applied to the third zone.

16. The apparatus of claim 6, wherein the first zone, the second zone, the third zone and the fourth zone are sequentially located in an outward direction from a center of the chuck, in a second direction and in a direction intersecting a third direction, the second direction perpendicular to the first direction, the direction intersecting the third direction perpendicular to the first direction and the second direction.

17. The apparatus of claim 1, further comprising:
an overlay distribution measuring device configured to measure the degree of overlay deterioration of the substrate and to transmit a measurement result thereof to the controller.

18. The apparatus of claim 17, wherein the controller is configured to set a plurality of new zones, based on object overlay distribution corresponding to the measurement result, and individually control respective magnitudes of the chucking force for the plurality of new zones.

19. An apparatus, comprising:
a chuck having an upper surface, the chuck configured to support a substrate on the upper surface of the chuck;
a fixing unit configured to generate a chucking force to fix the substrate to the chuck, and apply the chucking force to the substrate; and
a controller configured to divide the chuck into a plurality of zones and individually control respective magnitudes of the chucking force applied within the plurality of zones,
wherein the plurality of zones include
a first zone, defined in a position corresponding to a center of the chuck,
a second zone spaced apart from the first zone and including a region in a first angular direction,
a third zone spaced apart from the first zone and including a region in a second angular direction, the second angular direction different from the first angular direction, and
a fourth zone in a position different from the first zone in a radial direction of the chuck, and
the second zone and the third zone are between the fourth zone and the first zone.

20. An apparatus, comprising:
a chuck having an upper surface, the chuck configured to support a substrate on the upper surface of the chuck;
a fixing unit configured to generate a chucking force to fix the substrate to the chuck, and apply the chucking force to the substrate; and
a controller configured to divide the chuck into a plurality of zones and individually control respective magnitudes of the chucking force within the plurality of zones,
wherein the plurality of zones include
a first zone, defined in a position corresponding to a center of the chuck,
a second zone and a third zone, defined in a position corresponding to an outside of the first zone, and
a fourth zone, defined in a position corresponding to an outer edge of the chuck,
wherein the second zone and the third zone are between the first zone and the fourth zone, and
wherein the controller is configured to control a magnitude of the chucking force applied to the second zone and the third zone to be smaller than a magnitude of the chucking force applied to the first zone and the fourth zone.

21-24. (canceled)
